(19) United States
(12) Patent Application Publication
(10) Pub. No.: US 2012/0156827 A1
(43) Pub. Date: Jun. 21, 2012

(54) METHOD FOR FORMING CADMIUM TIN OXIDE LAYER AND A PHOTOVOLTAIC DEVICE

(75) Inventors: Joseph Darryl Michael, Delmar, NY (US); Bruce Edward Brackett, Crossville, TN (US); Kristian William Andreini, Burnt Hills, NY (US); Juan Carlos Rojo, Niskayuna, NY (US); Scott Feldman-Peabody, Golden, CO (US)

(73) Assignee: GENERAL ELECTRIC COMPANY, SCHENECTADY, NY (US)

(21) Appl. No.: 12/972,242

(22) Filed: Dec. 17, 2010

(51) Int. Cl. H01L 31/0256; H01L 31/0224; B05D 3/06

(52) U.S. Cl. 438/95; 427/558; 427/557; 438/98; 257/E31.003; 257/E31.126

(57) ABSTRACT

In one aspect of the present invention, a method is provided. The method includes disposing a substantially amorphous cadmium tin oxide layer on a support and rapidly thermally annealing the substantially amorphous cadmium tin oxide layer by exposing a first surface of the substantially amorphous cadmium tin oxide layer to an electromagnetic radiation to form a transparent layer. A method of making a photovoltaic device is also provided.

### BACKGROUND

The invention relates to methods for forming photovoltaic devices. More particularly, the invention relates to methods for forming polycrystalline cadmium tin oxide layer by rapid thermal annealing.

Thin film solar cells or photovoltaic devices typically include a plurality of semiconductor layers disposed on a transparent support, wherein one layer serves as a window layer and a second layer serves as an absorber layer. The window layer allows the penetration of solar radiation to the absorber layer, where the optical energy is converted to usable electrical energy. Cadmium telluride/cadmium sulfide (CdTe/CdS) heterojunction-based photovoltaic cells are one such example of thin film solar cells.

Typically, a thin layer of transparent conductive oxide (TCO) is deposited between the support and the window layer (for example, CdS) to function as a front contact current collector. However conventional TCOs, such as fluorine-doped tin oxide, indium tin oxide, and aluminum-doped zinc oxide, have high electrical resistivities at the thickness necessary for good optical transmission. The use of cadmium tin oxide (CTO) as TCO provides better electrical, optical, and mechanical properties, as well as stability at elevated temperatures. However, CdTe/CdS-based thin film solar cells still have challenges, for example, thick CdS films typically result in low device efficiencies from reduced short circuit current (J_{SC}) whereas thin CdS films can lead to reduced open circuit voltage (V_{OC}). In some instances, to achieve high device efficiencies with thin CdS films, a thin layer of a buffer material, such as an undoped tin oxide (SnO₂) layer, is intercalated between the cadmium tin oxide (CTO) and the window (CdS) layers.

The typical method used to manufacture the CTO layer includes depositing a layer of amorphous cadmium tin oxide on a support, followed by slow thermal annealing of the CTO layer, which is in contact or in close proximity with a CdS film, to achieve desired transparency and resistivity. However, CdS-based annealing of CTO is difficult to implement in a large-scale manufacturing environment. Specifically, it is very difficult to assemble and disassemble the plates before and after the annealing process, typically requiring manual intervention of the operator, and there is a high risk of misalignment that may result in the sublimation of the CTO film. Further, the use of expensive CdS on a non-reusable glass plate for each annealing step increases the cost of manufacturing. The high annealing temperatures (>550° C.) employed for thermal processing of the CTO film, further do not allow for the use of less expensive low softening temperature supports, such as, for example, soda-lime glass.

After crystallization of CTO is achieved, a separate buffer layer (for example, undoped tin oxide) is deposited on the CTO layer, which may be further followed by a second annealing step to obtain good crystalline quality. The performance of the buffer layer usually depends in part on the crystallinity and morphology of that layer and is affected by the surface of the CTO on which it is deposited. A high quality buffer layer is desirable to obtain the desired performance in the solar cells manufactured therefrom.

Thus, there is a need to reduce the number of steps for depositing and annealing of CTO and buffer layers during manufacturing of photovoltaic devices, resulting in reduced costs and improved manufacturing capability. Further, there is a need to provide cost-effective electrodes and photovoltaic devices manufactured using cadmium tin oxide having the desired electrical and optical properties.

### BRIEF DESCRIPTION OF THE INVENTION

Embodiments of the present invention are provided to meet these and other needs. One embodiment is a method. The method includes disposing a substantially amorphous cadmium tin oxide layer on a support and rapidly thermally annealing the amorphous cadmium tin oxide layer by exposing a first surface of the amorphous cadmium tin oxide layer to an electromagnetic radiation to form a transparent layer.

Another embodiment is a method of making a photovoltaic device. The method includes disposing a substantially amorphous cadmium tin oxide layer on a support and rapidly thermally annealing the amorphous cadmium tin oxide layer by exposing a first surface of the amorphous cadmium tin oxide layer to an electromagnetic radiation to form a transparent layer. The method further includes disposing a first semiconductor layer on the transparent layer; disposing a second semiconductor layer on the first semiconductor layer; and disposing a back contact layer on the second semiconductor layer to form a photovoltaic device.

Yet another embodiment is a method. The method includes disposing a substantially amorphous cadmium tin oxide layer on a support and rapidly thermally annealing the amorphous cadmium tin oxide layer by exposing a first surface of the amorphous cadmium tin oxide layer to an electromagnetic radiation to form a transparent layer. The transparent layer includes cadmium tin oxide having a substantially single-phase spinel crystal structure and has an electrical resistivity less than about 2×10⁻⁴ Ohms-cm.

### DRAWINGS

These and other features, aspects, and advantages of the present invention will become better understood when the following detailed description is read with reference to the accompanying drawings, wherein:

FIG. 1 is a schematic of a substantially amorphous cadmium tin oxide layer disposed on a support, according to an exemplary embodiment of the invention.

FIG. 2 is a schematic of a transparent electrode, according to an exemplary embodiment of the invention.

FIG. 3 is a schematic of a transparent electrode, according to an exemplary embodiment of the invention.

FIG. 4 is a schematic of a photovoltaic device, according to an exemplary embodiment of the invention.

FIG. 5 is a schematic of a photovoltaic device, according to an exemplary embodiment of the invention.

FIG. 6 is a schematic of a photovoltaic device, according to an exemplary embodiment of the invention.

FIG. 7 is a schematic of a photovoltaic device, according to an exemplary embodiment of the invention.

FIG. 8 is a schematic of a photovoltaic device, according to an exemplary embodiment of the invention.

FIG. 9A shows a digital image of an un-annealed substantially amorphous cadmium tin oxide layer.

FIG. 9B shows a digital image of a transparent layer, according to an exemplary embodiment of the invention.

FIG. 10 shows the optical transmission curves of a transparent layer, according to an exemplary embodiment of the invention.

FIG. 11 shows the sheet resistance values as a function of lamp power of a transparent layer, according to an exemplary embodiment of the invention.

FIG. 12 shows the XRD patterns of a transparent layer, according to an exemplary embodiment of the invention.

FIG. 13A shows a XPS profile of as-deposited substantially amorphous cadmium tin oxide layer.

FIG. 13B shows a XPS profile of a transparent layer, according to an exemplary embodiment of the invention.

FIG. 14 shows sheet resistance as a function of variac setting.

FIG. 15 shows sheet resistance as a function of pulse width.

FIG. 16 shows sheet resistance as a function of lamp energy.

FIG. 17 shows digital images of substantially amorphous cadmium tin oxide layer after each annealing step.

FIG. 18 shows the XRD patterns of a transparent layer, according to an exemplary embodiment of the invention.

FIG. 19 shows the absorption curves for amorphous cadmium tin oxide and crystalline cadmium tin oxide.

### DETAILED DESCRIPTION

As discussed in detail below, some of the embodiments of the invention provide a method for forming a crystalline cadmium tin oxide layer by rapid thermal annealing. The method may enable a cost-effective manufacturable process for forming crystalline cadmium tin oxide by eliminating the use of an expensive CdS/glass sacrificial part, typically used in proximity annealing. Further, the method allows for a continuous process obviating the need for manual intervention during the annealing process and the faster annealing times may lead to higher throughput and lower manufacturing costs. The rapid thermal annealing process also allows for use of less expensive supports having softening temperatures below 600° C., such as, for example, soda-lime glass.

Some of the embodiments of the invention further provide a method for forming transparent electrodes and photovoltaic devices having a graded cadmium tin oxide layer. The graded cadmium tin oxide layer may advantageously function as a transparent conductive oxide layer and a buffer layer in some embodiments or alternatively facilitate disposing of a crystalline buffer layer in some other embodiments, enabling enhanced crystallization and performance of the buffer layer. The graded cadmium tin oxide layer may thus provide cost reduction during fabrication of the photovoltaic device and enhanced device performance by decreasing the optical absorption in the window layers, reducing the total reflection, and optimizing the open-circuit voltage of the device.

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In some instances, the approximating language may correspond to the precision of an instrument for measuring the value.

In the following specification and the claims, the singular forms “a”, “an” and “the” include plural referents unless the context clearly dictates otherwise.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances, an event or capacity can be expected, while in other circumstances the event or capacity cannot occur—this distinction is captured by the terms “may” and “may be”.

The terms “transparent region”, “transparent layer” and “transparent electrode” as used herein, refer to a region, a layer, or an article that allows an average transmission of at least 80% of incident electromagnetic radiation having a wavelength in a range from about 300 nm to about 850 nm. As used herein, the term “disposed on” refers to layers disposed directly in contact with each other or indirectly by having intervening layers therebetween.

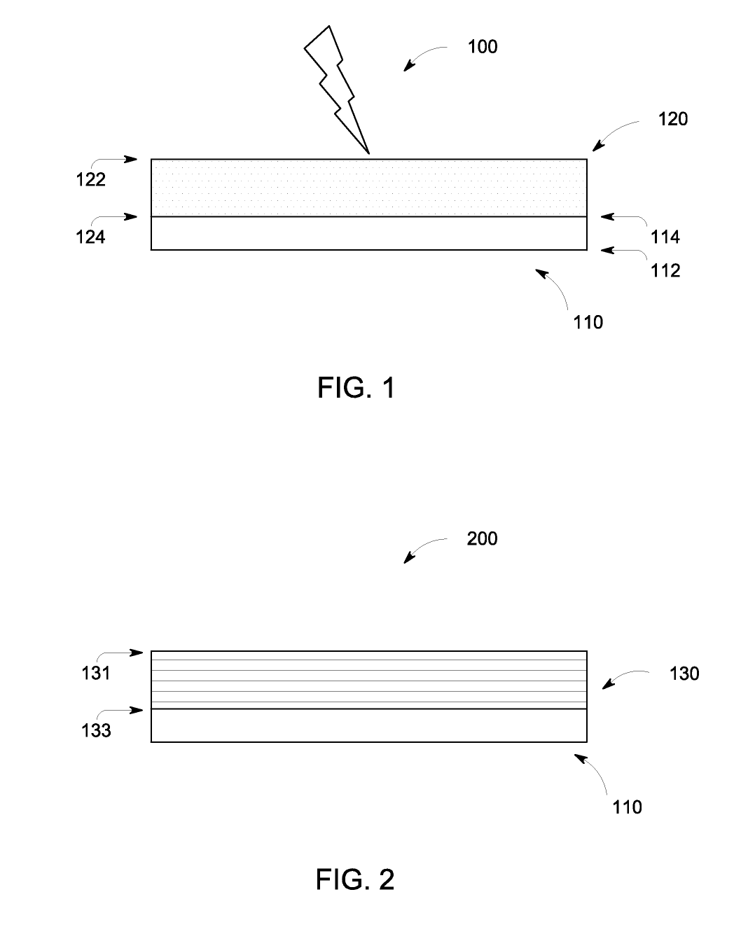

As discussed in detail below, some embodiments of the invention are directed to a method for forming an improved crystalline cadmium tin oxide layer for a transparent electrode and a photovoltaic device. The method is described with reference to FIGS. 1-8. As indicated, for example, in FIG. 1 the method includes disposing a substantially amorphous cadmium tin oxide layer 120 on a support 110. The substantially amorphous cadmium tin oxide layer 120 includes a first surface 122 and a second surface 124. In one embodiment, the second surface 124 is contiguous to the support 110.

As used herein, the term “cadmium tin oxide” includes a composition of cadmium, tin, and oxygen. In some embodiments, cadmium tin oxide includes a stoichiometric composition of cadmium and tin, wherein, for example, the atomic ratio of cadmium to tin is about 2:1. In some other embodiments, cadmium tin oxide includes a non-stoichiometric composition of cadmium and tin, wherein, for example, the atomic ratio of cadmium to tin is in range less than about 2:1 or greater than about 2:1. As used herein, the terms “cadmium tin oxide” and “CTO” may be used interchangeably. In some embodiments, cadmium tin oxide may further include one or more dopants, such as, for example, copper, zinc, calcium, yttrium, zirconium, hafnium, vanadium, tin, ruthenium, magnesium, indium, zinc, palladium, rhodium, titanium, or combinations thereof. “Substantially amorphous cadmium tin oxide” as used herein refers to a cadmium tin oxide layer that does not have a distinct crystalline pattern as observed by X-ray diffraction (XRD).

In certain embodiments, cadmium tin oxide may function as a transparent conductive oxide (TCO). Cadmium tin oxide as a TCO has numerous advantages including superior electrical, optical, surface, and mechanical properties and increased stability at elevated temperatures when compared to tin oxide, indium oxide, indium tin oxide, and other transparent conductive oxides. The electrical properties of cadmium tin oxide may depend in part on the composition of cadmium tin oxide characterized in some embodiments by the atomic concentration of cadmium and tin, or alternatively in some other embodiments by the atomic ratio of cadmium to tin in cadmium tin oxide. Atomic ratio of cadmium to tin, as used herein, refers to the ratio of atomic concentration of cadmium to tin in cadmium tin oxide. Atomic concentrations of cadmium and tin and the corresponding atomic ratio are commonly measured using, for instance, x-ray photoelectron spectroscopy (XPS).

In one embodiment, the atomic ratio of cadmium to tin in the substantially amorphous CTO layer 120 is in a range from about 1.2:1 to about 3:1. In another embodiment, the atomic ratio of cadmium to tin in the substantially amorphous CTO layer 120 is in a range from about 1.5:1 to about 2.5:1. In yet another embodiment, the atomic ratio of cadmium to tin in the substantially amorphous CTO layer 120 is in a range from about 1.7:1 to about 2.15:1. In one particular embodiment, the atomic ratio of cadmium to tin in the substantially amorphous CTO layer 120 is in a range from about 1.4:1 to about 2:1.

In one embodiment, atomic concentration of cadmium in the substantially amorphous CTO layer 120 is in a range from about 20% to about 40% of the total atomic content of cadmium tin oxide. In another embodiment, atomic concentration of cadmium in the substantially amorphous CTO layer 120 is in a range from about 25% to about 35% of the total atomic content of cadmium tin oxide. In a particular embodiment, atomic concentration of cadmium in the substantially amorphous CTO layer 120 is in a range from about 28% to about 32% of the total atomic content of cadmium tin oxide. In one embodiment, atomic concentration of tin in the substantially amorphous CTO layer 120 is in a range from about 10% to about 30% of the total atomic content of cadmium tin oxide. In another embodiment, atomic concentration of tin in the substantially amorphous CTO layer 120 is in a range from about 15% to about 28% of the total atomic content of cadmium tin oxide. In a particular embodiment, atomic concentration of tin in the substantially amorphous CTO layer 120 is in a range from about 18% to about 24% of the total atomic content of cadmium tin oxide. In one embodiment, atomic concentration of oxygen in the substantially amorphous CTO layer 120 is in a range from about 30% to about 70% of the total atomic content of cadmium tin oxide. In another embodiment, atomic concentration of oxygen in the substantially amorphous CTO layer 120 is in a range from about 40% to about 60% of the total atomic content of cadmium tin oxide. In a particular embodiment, atomic concentration of oxygen in the substantially amorphous CTO layer 120 is in a range from about 44% to about 50% of the total atomic content of cadmium tin oxide.

In one embodiment, the substantially amorphous CTO layer 120 is disposed on the support 110 by any suitable technique, such as sputtering, chemical vapor deposition, spin coating, spray coating, or dip coating. In one embodiment, the substantially amorphous CTO layer 120 may be formed by dipping a support 110 into a solution of a reaction product containing cadmium and tin derived from a cadmium compound and a tin compound.

In a particular embodiment, the substantially amorphous CTO layer 120 is disposed on the support 110 by sputtering. In one embodiment, the substantially amorphous CTO layer 120 may be disposed on the support 110 by radio frequency (RF) sputtering or direct current (DC) sputtering. In one embodiment, the substantially amorphous CTO layer 120 may be disposed on the support 110 by reactive sputtering in the presence of oxygen.

In some embodiments, a substantially amorphous CTO layer 120 is disposed on the support 110 using a ceramic cadmium tin oxide target. In some other embodiments, a substantially amorphous CTO layer 120 is disposed on the support 110 by co-sputtering using cadmium oxide and tin oxide targets or by sputtering from a single target including a blend of cadmium oxide and tin oxide. In some other embodiments, a substantially amorphous CTO layer 120 is disposed on the support 110 by reactive sputtering using a single metallic target, wherein the metal target includes a mixture of cadmium and tin metals or by reactive co-sputtering using two different metal targets, that is, a cadmium target and a tin target. The sputtering target(s) may be manufactured, formed, or shaped by any process and in any shape, composition, or configuration suitable for use with any appropriate sputtering tool, machine, apparatus, or system.

When depositing a substantially amorphous CTO layer 120 on the support 110 by sputtering, the atomic concentration of cadmium and tin in the deposited layer may be directly proportional to the atomic concentration of cadmium and tin in the sputtering target(s). In one embodiment, the atomic ratio of cadmium to tin in the sputtering target(s) is in a range from about 1.4:1 to about 3:1. In another embodiment, the atomic ratio of cadmium to tin in the sputtering target(s) is in a range from about 1.5:1 to about 2.5:1. In yet another embodiment, the atomic ratio of cadmium to tin in the sputtering target(s) is in a range from about 1.7:1 to about 2.15:1. In one particular embodiment, the atomic ratio of cadmium to tin in sputtering target(s) is in a range from about 1.4:1 to about 2:1.

In some embodiments, the thickness of the substantially amorphous CTO layer 120 is controlled by varying one or more of the processing parameters employed during the disposing step. In one embodiment, the thickness of the substantially amorphous CTO layer 120 is engineered to be in a range from about 50 nm to about 600 nm. In another embodiment, the substantially amorphous CTO layer 120 has a thickness in a range from about 100 nm to about 500 nm. In a particular embodiment, the substantially amorphous CTO layer 120 has a thickness in a range from about 200 nm to about 400 nm.

As indicated, for example, in FIG. 1, the support 110 further includes a first surface 112 and a second surface 114. In one embodiment, the solar radiation is incident on the first surface 112 and the substantially amorphous CTO layer 120 is disposed adjacent to the second surface 114. In such instance, the configuration of the support 110 and CTO layer 120 is also referred to as “superstrate” configuration. In one embodiment, the support 110 is transparent over the range of wavelengths for which transmission through the support 110 is desired. In one embodiment, the support 110 may be transparent to visible light having a wavelength in a range from about 400 nm to about 1000 nm. In yet another embodiment, the thermal expansion coefficient of the support 110 is close to the thermal expansion coefficient of the substantially amorphous CTO layer 120 to prevent cracking or buckling of the substantially amorphous CTO layer 120 during heat treatment. In some embodiments certain other layers may be disposed between the substantially amorphous CTO layer 120 and the support 110, such as, for example, a reflective layer.

In some embodiments, the support 110 includes a material capable of withstanding heat treatment temperatures greater than about 600° C., such as, for example silica and borosilicate glass. In some other embodiments, the support 110 includes a material that has a softening temperature lower than 600° C., such as, for example, soda-lime glass. Typically, it is not possible to use supports such as soda-lime glass for annealing of CTO because the annealing temperatures employed are greater than 600° C., which is greater than the softening temperature of soda-lime glass. Thus, use of supports such as soda lime glass is not feasible for fabrication of photovoltaic devices wherein temperatures greater than 600° C. are employed for annealing. In some embodiments, the rapid thermal annealing step of the present invention results in a rapid temperature increase of support-amorphous CTO assembly and avoids continuous exposure of the support to temperatures greater than 600° C. for an extended time period. Without being bound by any particular theory, it is believed that the rapid thermal annealing step may heat the amorphous CTO layer much faster than the support due to the greater absorption of energy by the amorphous CTO layer. Accordingly, in some embodiments, the rapid thermal annealing step may allow the amorphous CTO layer to be heated to a temperature greater than the support, thus annealing the CTO layer without softening the support. In some embodiments, the method advantageously allows for use of low softening temperature (less than 600° C.) supports, such as, for example, soda-lime glass for forming a photovoltaic device.

In some other embodiments, as illustrated for example in FIG. 2, the substantially amorphous CTO layer 120 is disposed on a support 110, such that the solar radiation is incident on the first surface 131 of the transparent layer and the second surface 133 of the transparent layer is disposed adjacent to the second surface 114 of the support 110. In such instances, the configuration of the support 110 and CTO layer 120 is also referred to as “substrate” configuration. The support 110 includes a stack of a plurality of layers as illustrated FIG. 6, such as, for example, a back contact layer 160 disposed on a back support 190, a second semiconducting layer 150 disposed on the back contact layer 160, and a first semiconducting layer 140 disposed on the second semiconducting layer 150. In such embodiments, the substantially amorphous CTO layer 120 is disposed on the first semiconducting layer 140.

As indicated, for example, in FIG. 1, the method further includes exposing a first surface of the substantially amorphous CTO layer 122 to an electromagnetic radiation 100. As indicated, for example, in FIG. 2, the method furthermore includes rapidly thermally annealing the substantially amorphous CTO layer 120 to form a transparent layer 130. In some embodiments, the transparent layer 130 disposed on the support 110 forms a transparent electrode 200.

The terms “rapidly thermally annealing” and “rapid thermal annealing”, as used herein, refer to irradiating a surface of the substantially amorphous CTO layer 120 at an incident power density in a range greater than about 200 Watts/cm² to form substantially crystalline CTO layer. The term “incident power density” as used herein refers to the power incident on the first surface 122 of the substantially amorphous CTO layer 120 per unit surface area. In some embodiments, rapid thermally annealing further includes irradiating a surface of the substantially amorphous CTO layer 120 at an incident power density such that the heating rate that the substantially amorphous CTO layer is subjected to is greater than about 20° C./second. The term “heating rate”, as used herein, refers to the average rate at which the amorphous CTO layer is heated at to reach the desired annealing temperature. In certain embodiments, rapid thermally annealing includes irradiating a surface of the substantially amorphous CTO layer 120 at an incident power density such that the heating rate that the substantially amorphous CTO layer is subjected to is greater than about 100° C./second. In some other embodiments, rapid thermally annealing further includes irradiating a surface of the substantially amorphous CTO layer 120 at an incident power density and at a heating rate such that the time taken to reach the desired annealing temperature is less than about 60 seconds.

The term “electromagnetic radiation” as used herein refers to radiation that has both electric and magnetic fields and travels in waves. Electromagnetic radiation may be classified by wavelength into radio, microwave, infrared, visible region, ultraviolet, X-rays and gamma rays. In one embodiment, rapid thermal annealing of the substantially amorphous CTO layer 120 includes exposing the substantially amorphous CTO layer 120 to a high intensity electromagnetic radiation such that controlled annealing of the substantially amorphous CTO layer 120 is achieved. In one embodiment, rapid thermal annealing of the substantially amorphous CTO layer 120 includes exposing the substantially amorphous CTO layer 120 to a high intensity infra-red radiation 100 such that the substantially amorphous CTO layer 120 absorbs a significant portion of light photons. “Infra-red radiation” includes electromagnetic waves having a wavelength in a range greater than about 700 nm.

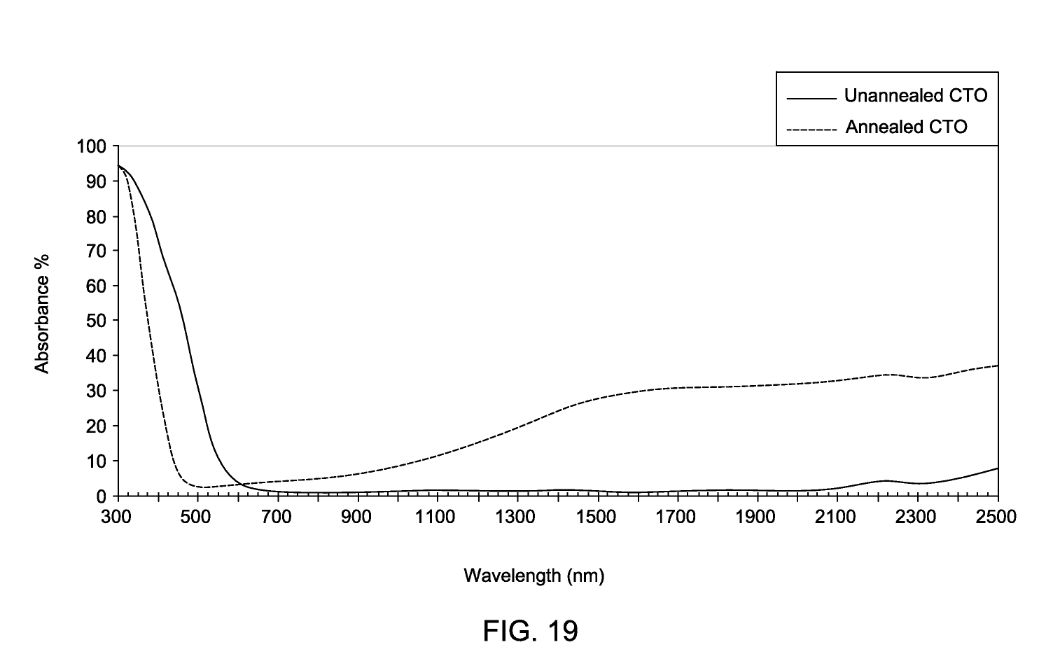

In one embodiment, rapid thermal annealing of the substantially amorphous CTO layer 120 includes exposing the substantially amorphous CTO layer 120 to a high intensity electromagnetic radiation with a defined intensity-wavelength spectrum such that the substantially amorphous CTO layer 120 absorbs a significant portion of light photons. FIG. 19 shows an illustrative absorption curve for unannealed amorphous CTO and crystalline CTO as a function of electromagnetic radiation wavelength. As illustrated in FIG. 19, the absorption profile of the crystalline CTO layer is different than the absorption profile of amorphous CTO layer. Accordingly, in some embodiments, the optical properties of the amorphous and crystalline CTO may be advantageously used to provide rapid thermal annealing in a controlled manner.

As illustrated in FIG. 4, amorphous, unannealed CTO has a very high optical absorption (greater than 90%) for photons with wavelengths smaller than 300 nm. Similarly, crystalline CTO has substantially the same optical absorption for photons with wavelengths smaller than 300 nm (greater than 30%). In one embodiment, the substantially amorphous CTO layer 120 is exposed to electromagnetic radiation having a wavelength in a range less than about 300 nm. In such instances, the electromagnetic radiation may be subjected to a filter such that radiation having a wavelength greater than about 300 nm is removed from the incident radiation. The large amount of photons absorbed by the amorphous CTO layer in this wavelength range may lead to rapid rise in temperature within the film resulting in a change from amorphous to crystalline form very quickly. Without being bound by any theory it is believed that by using a wavelength in a range less than about 300 nm, the amount of incident power density absorbed by the substantially amorphous CTO layer is substantially the same as the power density absorbed by the substantially crystalline CTO layer. Accordingly, in such instances the heating rate of the substantially crystalline CTO layer is substantially the same as the substantially amorphous CTO layer, thus reducing the possibility of over-heating the crystalline CTO layer. Use of wavelengths less than 300 nm may thus allow for more stable annealing of the amorphous CTO layer as changes in optical properties of the CTO layer after annealing may not affect the power absorbed by the layer. In some embodiments, the method includes exposing a first surface 122 of the substantially amorphous CTO layer 120 to ultra-violet radiation 100 having a wavelength in a range less than about 300 nm. The term “a wavelength in a range” refers to electromagnetic radiation having a spectrum of wavelengths in that range and is not limited to a single wavelength or monochromatic radiation.

In another embodiment, the electromagnetic radiation employed for rapid thermal annealing has a wavelength in a range less than about 600 nm. As illustrated in FIG. 19, the absorption profile of crystalline CTO shows a significant reduction in absorption between a wavelength range of about 350 nm to 600 nm Accordingly, in such instances, the amount of incident power density absorbed by the crystalline CTO layer is lower than the power density absorbed by the substantially amorphous CTO layer. Accordingly, in such embodiments, the heating rate of the substantially crystalline CTO layer may be lower than the substantially amorphous CTO layer, thus reducing the possibility of over-heating of the crystalline CTO layer.

In yet another embodiment, the electromagnetic radiation employed for rapid thermal annealing has a wavelength in a range from about 450 nm to about 600 nm. Without being bound by any theory, it is believed that as the substantially amorphous CTO layer 120 becomes crystalline, optical absorption decreases since crystalline CTO is substantially transparent to electromagnetic radiation in the wavelength range of 450 nm to 600 nm, as illustrated in FIG. 19. Reduced optical absorption as the CTO crystallizes may result in significantly reduced heating of the crystalline CTO layer due to electromagnetic radiation. Accordingly, in such instances, the rapid thermal annealing process may function essentially as a “self-limiting” process, that is, the act of crystallization prevents the CTO layer from becoming over-heated to the point of damaging the layer. The selected wavelength range employed for rapid thermal annealing may depend in part on the optical characteristics of the amorphous CTO layer, the optical properties of the crystalline CTO layer, and the photon spectrum of the electromagnetic radiation used.

In some embodiments, rapid thermal annealing of the substantially amorphous CTO layer 120 includes exposing a first surface 122 to electromagnetic radiation emitted from an incoherent light source. The term “light” as used herein refers to electromagnetic radiation as defined above. The term “incoherent light source” as used herein refers to a source of light configured to emit light waves of different wavelengths or light waves having same wavelengths but out of phase with each other as opposed to coherent light wherein the light waves are in phase with each other. The term “incoherent light source” as used herein further refers to a single light source or a plurality of light sources.

In one embodiment, the incoherent light source is selected from any suitable light source configured to emit light or electromagnetic radiation having wavelength in the desired range. In some embodiments, the incoherent light source is selected from a group consisting of a halogen lamp, an ultra-violet lamp, a high intensity discharge lamp, and combinations thereof. In a particular embodiment, the incoherent light source includes a halogen lamp or an array of halogen lamps.

In some embodiments, the incoherent light source may be further configured to emit electromagnetic radiation in a pulsed manner. In some embodiments, the incoherent light source may emit electromagnetic radiation at a fixed pulsed width. The term “pulse width” as used herein refers to the time duration for which the amorphous CTO layer is exposed to electromagnetic radiation 100.

The incoherent light source may be characterised in part by one or more of the incident power density, lamp power, or pulse width. In one embodiment, the incoherent light source may have an incident power density in a range from about 100 watts/cm² to about 500 watts/cm². In one particular embodiment, the incoherent light source may have an incident power density in a range from about 200 watts/cm² to about 400 watts/cm².

In one embodiment, the incoherent light source may be characterised by a lamp power in a range from about 1.4 kW to about 2 kW. In one particular embodiment, the incoherent light source may be characterised by a lamp power in a range from about 1.4 kW to about 1.8 kW. As noted above, rapid thermal annealing step may include a single lamp having a power 1.4 kW to about 1.8 kW in some embodiments or a plurality of lamps, each having a power in a range from about 1.4 kW to about 1.8 kW, in some other embodiments.

In some embodiments, the first surface 122 of the substantially amorphous CTO layer 120 is exposed to an incoherent light source at a fixed pulse width. In some other embodiments, the first surface 122 of the substantially amorphous CTO layer 120 is exposed to an incoherent light source at a variable pulse width. In one embodiment, the substantially amorphous CTO layer 120 is exposed to the electromagnetic radiation 100 for a time duration in a range from about 1 second to about 120 seconds. In another embodiment, the substantially amorphous CTO layer 120 is exposed to the electromagnetic radiation 100 for a time duration in a range from about 5 seconds to about 80 seconds. In a particular embodiment, the substantially amorphous CTO layer 120 is exposed to the electromagnetic radiation 100 for a time duration in a range from about 10 seconds to about 40 seconds.

In some embodiments, the rapid thermal annealing step may be further repeated n times, wherein n is a range in a range from 2 to 20. In a particular embodiment the rapidly thermal annealing step may be repeated 2-8 times. For embodiments involving repetition of thermal annealing step, the pulse width may be the same for each thermal annealing step or may be different for the different annealing steps. The number of thermal annealing steps or the pulse width may vary depending in part on the thickness of the support 110, thickness of the substantially amorphous CTO layer 120, or the incident power density.

The electromagnetic radiation is absorbed by the substantially amorphous CTO layer 120 and converted into thermal energy resulting in a rapid increase in temperature of the layer to a treatment temperature. Without being bound by theory, it is believed that the rapid increase in temperature within the layer causes a change from substantially amorphous CTO to a substantially crystalline CTO. The percentage conversion of substantially amorphous CTO to substantially crystalline CTO may depend in part on the amount of incident power density absorbed by the substantially amorphous CTO layer 120 and the thermal losses from the layer 120. In one embodiment, the substantially amorphous CTO 120 layer absorbs at least 80 percent of the incident power density. In another embodiment, the substantially amorphous CTO layer 120 absorbs at least 50 percent of the incident power density. In a particular embodiment, the substantially amorphous CTO layer 120 absorbs at least 10 percent of the incident power density. As noted earlier, in some embodiments, the amount of power density absorbed by the substantially amorphous CTO layer 120 may be advantageously controlled in part by tuning the energy wavelength spectra of the electromagnetic radiation 100. In such instances, by controlling the amount of power density absorbed by the substantially amorphous CTO layer one or more of the heating rate or the treatment temperature may be controlled.

In one embodiment, the substantially amorphous CTO layer 120 is heated at a treatment temperature in a range from about 700° C. to about 1200° C. In another embodiment, the substantially amorphous CTO layer is heated at a treatment temperature in a range from about 700° C. to about 900° C. In a particular embodiment, the substantially amorphous CTO layer is heated at a treatment temperature in a range from about 800° C. to about 900° C. Treatment temperature as used refers to the temperature of the substantially amorphous CTO layer after being exposed to the electromagnetic radiation for a time duration sufficient for the rapid thermal annealing step.

The rapidly thermal annealing process is further controlled by varying the pressure conditions employed during rapid thermal annealing. In one embodiment, rapid thermal annealing is carried out under vacuum conditions, defined here in as pressure conditions less than atmospheric pressure. In some embodiments, rapid thermal annealing may be carried out in the presence of argon gas at a constant pressure. In some other embodiments, rapid thermal annealing may be carried out under dynamic pressure by continuous pumping. In one embodiment, rapid thermal annealing is conducted in the presence of argon gas at a pressure equal to or less than about 700 Torr. In another embodiment, rapid thermal annealing is conducted in the presence of argon gas at a pressure equal to or less than about 500 Torr. In yet another embodiment, rapid thermal annealing is conducted in the presence of argon gas at a pressure equal to or less than about 250 Torr.

As noted above, rapid thermal annealing of the substantially amorphous CTO layer 120 results in formation of a transparent layer 130. In one embodiment, the transparent layer 130 includes a substantially uniform single-phase polycrystalline CTO, formed for example, by annealing the substantially amorphous CTO layer 120. In some embodiments, the substantially crystalline cadmium tin oxide has an inverse spinel crystal structure. The substantially uniform single-phase crystalline CTO that forms the transparent layer 130 is referred to herein as “cadmium tin oxide” as distinguished from a “substantially amorphous CTO” layer 120 that is disposed on the support 110 and thermally treated to form the transparent layer 130. In some embodiments, the transparent layer may have the desired electrical and optical properties and may function as a transparent conductive oxide (TCO) layer. In some embodiments, the transparent layer 130 may further include an amorphous component, such as for example, amorphous cadmium oxide, amorphous tin oxide, or combinations thereof.

The transparent layer may be further characterised by one or more of thickness, electrical properties, or optical properties. In one embodiment, the transparent layer 130 has a thickness in a range from about 100 nm to about 600 nm In another embodiment, the transparent layer 130 has a thickness in a range from about 150 nm to about 450 nm. In a particular embodiment, the transparent layer 130 has a thickness in a range from about 100 nm to about 400 nm. In some embodiments, the transparent layer 130 has an average electrical resistivity (ρ) that is less than about 4×10⁻⁴ Ohms-cm. In some other embodiments, the transparent layer 130 has an average electrical resistivity (ρ) that is less than about 2×10⁻⁴ Ohms-cm. In some embodiments, the transparent layer 130 has an average optical transmission greater than about 80%. In some other embodiments, the transparent layer 130 has an average optical transmission greater than about 95%.

As noted herein earlier, the rapid thermal annealing step is carried out in the absence of a CdS film or an external source of cadmium that is conventionally used for annealing cadmium tin oxide. Accordingly, the rapid thermal annealing step of the present invention eliminates the additional step of preparing a “sacrificial” CdS film on a non reusable-support that is later used for annealing of cadmium tin oxide by placing the CdS film adjacent to the cadmium tin oxide layer or in close proximity to the cadmium tin oxide layer being annealed. Further, the rapid thermal annealing step also reduces the amount of CdS used in the fabrication of a photovoltaic device, and is economically advantageous as CdS is an expensive material. The method also allows for a continuous process for forming the CTO layer with minimal intervention that is typically needed for assembly/disassembly of the CTO and the CdS layers before and after the annealing process. Accordingly, the rapid thermal annealing process also results in reduced processing time leading to higher throughputs, which may lead to lower manufacturing costs.

In one embodiment, the transparent layer 130, as indicated, for example, in FIG. 2 includes a substantially homogeneous concentration of cadmium tin oxide across the thickness of the layer 130. In such instance, the atomic concentrations of cadmium and tin in the transparent layer are substantially constant across the thickness of the layer. The term “substantially constant” as used herein means that the variation in the atomic concentrations of cadmium and tin is less than about 10% across the thickness of the transparent layer 130.

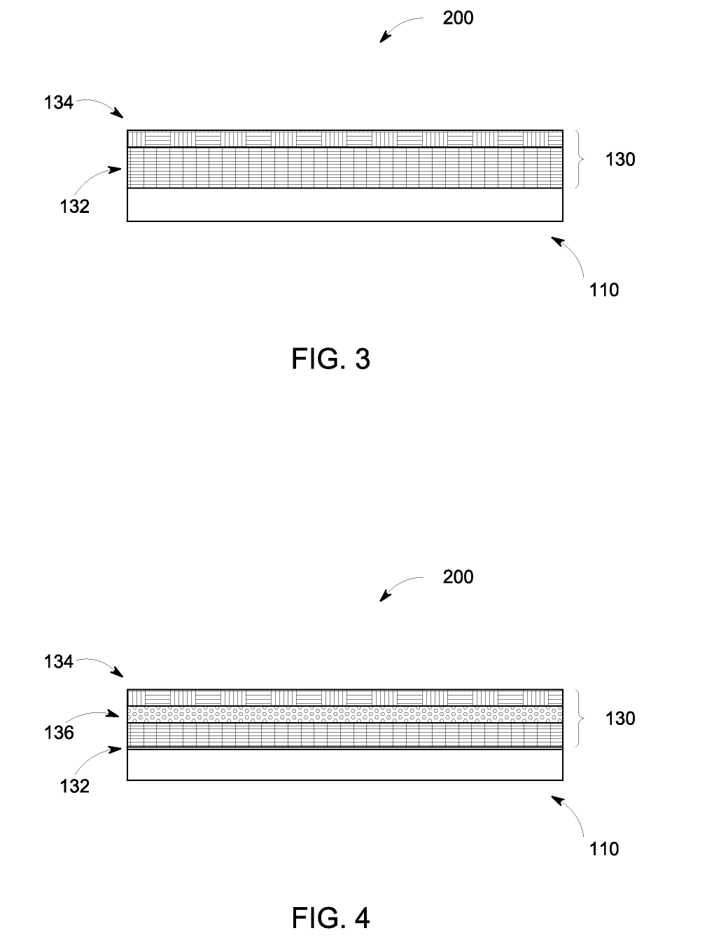

In another embodiment, the transparent layer, as indicated, for example, in FIG. 3, includes a first region 132 and a second region 134. The first region 132 includes cadmium tin oxide and the second region 134 includes tin and oxygen. In some embodiments, the second region 134 further includes cadmium and an atomic concentration of cadmium in the second region 134 is lower than an atomic concentration of cadmium in the first region 132. Accordingly, in such instances, rapid thermal annealing of the substantially amorphous CTO layer 120 results in formation of a transparent layer 130 having a cadmium-depleted region within the second region 134.

In one embodiment, the first region 132 includes cadmium tin oxide having a substantially single-phase spinel crystal structure. As noted herein earlier with respect to the transparent layer 130, the first region 132 within the transparent layer 130 functions as a TCO layer in some embodiments. The electrical properties of the first region 132 may depend in part on the composition of cadmium tin oxide characterized in some embodiments by the atomic concentration of cadmium and tin, or alternatively in some other embodiments by the atomic ratio of cadmium to tin in cadmium tin oxide. Accordingly, in some embodiments the atomic ratio of cadmium to tin in the first region 132 may be advantageously engineered to provide the desired electrical properties.

In one embodiment, the atomic ratio of cadmium to tin in the first region 132 is in a range from about 1.2:1 to about 3:1. In another embodiment, the atomic ratio of cadmium to tin in the first region 132 is in a range from about 1.5:1 to about 2.5:1. In yet another embodiment, the atomic ratio of cadmium to tin in the first region 132 is in a range from about 1.7:1 to about 2.15:1. In one particular embodiment, the atomic ratio of cadmium to tin in the first region 132 is in a range from about 1.4:1 to about 2:1.

In one embodiment, the atomic ratio of cadmium to tin in the first region 132 is substantially constant across a thickness of the first region 132. The term “substantially constant” as used herein means that the variation in the atomic ratio of cadmium to tin is less than about 10% across the thickness of the first region 132. In one embodiment, the first region 132 has a thickness in a range from about 100 nm to about 500 nm. In another embodiment, the first region 132 has a thickness in a range from about 150 nm to about 450 nm. In a particular embodiment, the first region 132 has a thickness in a range from about 100 nm to about 400 nm. In some embodiments, the higher conductivity of the first region 132 may complement the optical transmission. Higher conductivity or lower resistivity of the first region 132 may allow for thinner first region, which further increases the optical transmission.

The transparent layer 130 further includes a second region 134 including tin and oxygen that is formed by rapid thermal annealing of the substantially amorphous CTO layer 120. In some embodiments, the second region 134 is formed by non-stoichiometric sublimation of cadmium from cadmium tin oxide at processing conditions employed during rapid thermal annealing. Without being bound by theory, it is believed that the vapor pressure of cadmium above the amorphous CTO layer 120 is higher than that of tin, resulting in cadmium depletion at the surface during thermal processing. In some embodiments, controlled depletion of cadmium from the surface results in formation of the second region 134 having controlled thickness, morphology, and composition.

In some embodiments, the second region 134 may have an electrical resistivity greater than the electrical resistivity of the first region 132. In some embodiments, the first region 132 may function as a TCO layer and the second region 134 may function as a buffer layer. Thus, in some embodiments, the method includes advantageously engineering the composition of the transparent layer 130 to vary across the thickness of the layer such that the transparent layer 130 functions both as a TCO layer and a buffer layer. In some other embodiments, the second region 134 may assist the nucleation of a separately deposited crystalline buffer (for example, tin oxide) layer on the transparent layer 130 resulting in a higher quality buffer layer.

As described above with reference to the first region 132, the electrical properties of the second region 134 may also depend in part on the composition of the second region 134 or the concentration of cadmium to tin in the second region 134. In some embodiments, the second region 134 includes tin oxide. In some embodiments, the second region 134 further includes cadmium. In one embodiment, the atomic concentration of cadmium in the second region 134 is less than about 20%. In another embodiment, the atomic concentration of cadmium in the second region 134 is less than about 10%. In a particular embodiment, the atomic concentration of cadmium in the second region 134 is less than about 0.5%.

In some other embodiments, the second region 134 is substantially free of cadmium. Substantially free of cadmium as used herein means that the atomic concentration of cadmium in the second region 134 is less than about 0.01%. In one embodiment, the atomic concentration of cadmium in the second region 134 is less than about 0.001%. In one embodiment, the atomic concentration of cadmium in the second region 134 is about 0%.

In some embodiments, the atomic ratio of cadmium to tin in the second 134 region is substantially constant across a thickness of the second region 134. As noted earlier, the term “substantially constant” as used herein means that the variation in the atomic ratio of cadmium to tin is less than about 10% across the thickness of the second region 134. In some embodiments, the thickness of the second region 134 is controlled by varying one or more of treatment temperature, time duration, and vacuum conditions employed during the rapid thermal annealing process. In one embodiment, the thickness of the second region 134 is engineered to be in a range from about 10 nm to about 300 nm. In another embodiment, the second region 134 has a thickness in a range from about 50 nm to about 250 nm. In a particular embodiment, the second region 134 has a thickness in a range from about 20 nm to about 200 nm.

As indicated, for example, in FIG. 4, the transparent layer 130 further includes a transition region 136 interposed between the first region 132 and the second region 134, in some embodiments. The transition region 136 includes cadmium, tin and oxygen and the atomic ratio of cadmium to tin in the transition region 136 varies across the thickness of the transition region 136. In one particular embodiment, the atomic ratio of cadmium to tin in the transition region 136 decreases from the first region 132 to the second region 134.

In some embodiments, the transition region 136 includes a continuous gradient of atomic concentration of cadmium and tin. The continuous gradient of atomic concentrations of cadmium and tin in the transition region 136 allows for continuous transition of composition between the first region 132 (functioning as a transparent conductive oxide (TCO) layer) and the second region 134 (functioning as a buffer layer). Thus, the graded cadmium tin oxide (CTO) layer of the present invention substantially eliminates the discontinuous interface between the TCO layer and the buffer layer characteristic of device structures that are fabricated by depositing first the TCO layer and then the buffer layer. The presence of discontinuous interfaces between functional layers in thin film solar cells may result in one or more of optical losses, electrical losses, or adhesion variability.

In some embodiments, the thickness of the transition region 136 is controlled by varying one or more of treatment temperature, time duration, and vacuum conditions employed during the rapid thermal annealing process. In one embodiment, the thickness of the transition region 136 is engineered to be in a range from about 10 nm to about 200 nm. In another embodiment, the transition region 136 has a thickness in a range from about 20 nm to about 150 nm. In a particular embodiment, the transition region 136 has a thickness in a range from about 40 nm to about 100 nm.

The first region 132 and the second region 134 may be further characterized by their electrical and optical properties. In some embodiments, the second region 134 has an electrical resistivity that is greater than the electrical resistivity of the first region 132 by a factor of 1000. In some other embodiments, the second region 134 has an electrical resistivity that is greater than the electrical resistivity of the first region 132 by a factor of 100. In certain embodiments, the second region 134 has an electrical resistivity that is greater than the electrical resistivity of the first region 132 by a factor of 50.

In some embodiments, the first region 132 has an average electrical resistivity (ρ) that is less than about 4×10⁻⁴ Ohms-cm. In some other embodiments, the first region 132 has an average electrical resistivity (ρ) that is less than about 2×10⁻⁴ Ohms-cm. In some embodiments, the second region 134 has an average electrical resistivity (ρ) that is greater about 10⁻³ Ohms-cm. In some embodiments, the second region 134 has an average electrical resistivity (ρ) that is greater about 10⁻² Ohms-cm. The first region 132 and the second region 134 further have an average optical transmission greater than about 80%. In some embodiments, the transparent electrode 200 as indicated, for example, in FIGS. 2-4 has an average optical transmission greater than about 80%. In some other embodiments, the transparent electrode 200 has an average optical transmission greater than about 95%.

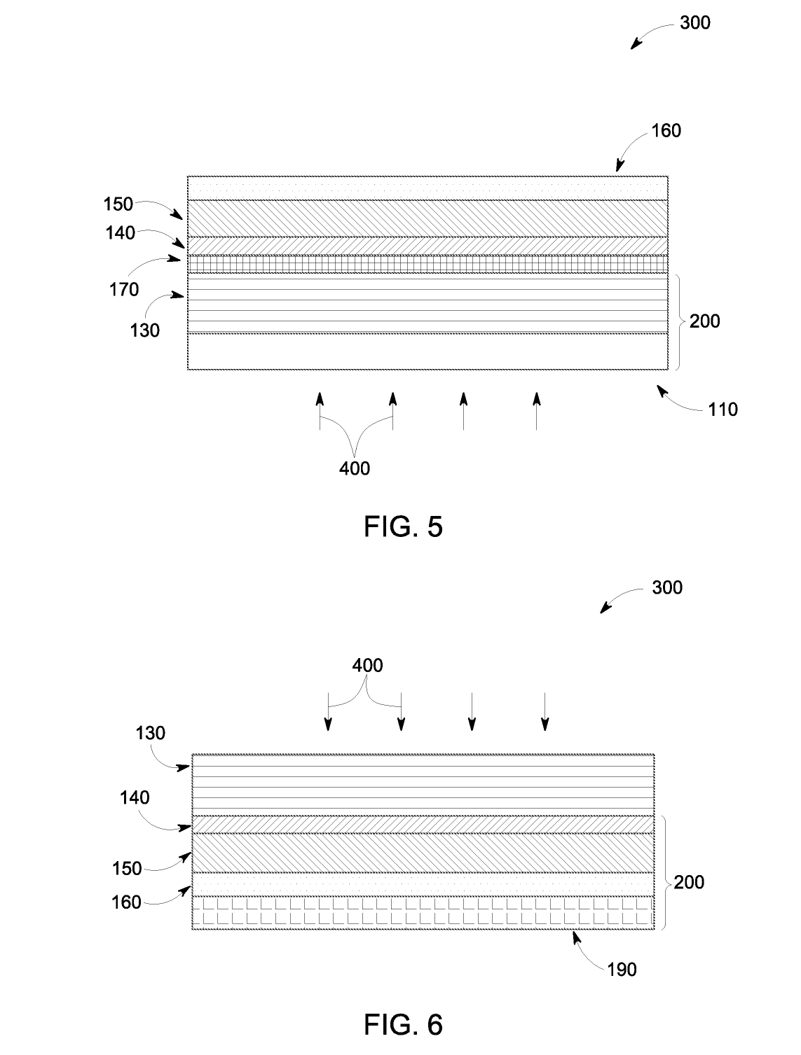

As discussed in detail below, some embodiments of the invention are further directed to methods for making photovoltaic devices. The method is described with reference to FIGS. 1-8. As indicated, for example, in FIG. 1, the method includes disposing a substantially amorphous CTO layer 120 on a support 110. The substantially amorphous CTO layer 120 includes a first surface 122 and a second surface 124. Further, as indicated, for example, in FIG. 1 the method includes exposing a first surface of the amorphous cadmium tin oxide layer 122 to an electromagnetic radiation 100. The method further includes rapidly thermally annealing the substantially amorphous CTO layer 120 to form a transparent layer 130, as indicated in FIG. 2. In some embodiments, the transparent layer 130 disposed on the support 110 forms a transparent electrode 200. As indicated, for example, in FIG. 5 the method further includes disposing a first semiconductor layer 140 on the transparent layer 130; disposing a second semiconductor layer 150 on the first semiconductor layer 140; and disposing a back contact layer 160 on the second semiconductor layer 150 to form a photovoltaic device 300. As noted herein earlier, the rapid thermal annealing step obviates the need for one or more additional manufacturing steps employed during conventional annealing of substantially amorphous CTO using a CdS film. The configuration as shown in FIG. 5 is typically referred to as “superstrate” configuration, wherein the solar radiation 400 is incident on the support 110. Accordingly, in such a configuration, it is desirable that the support 110 is substantially transparent.

In one embodiment, the method of making a photovoltaic device in “substrate” configuration is provided. The method includes forming a transparent layer 130 as described earlier on a support 110, such that the solar radiation 400 is incident on transparent layer 130, as shown in FIG. 6. In such embodiment, the support 110 includes a back contact layer 160 disposed on a back support 190, a second semiconducting layer 150 disposed on the back contact layer 160, a first semiconducting layer 140 disposed on the second semiconducting layer 150, and the transparent layer 130 disposed on the first semiconducting layer 140. In such a configuration as solar radiation is incident on the transparent layer 130, the back support may include a metal. In some other embodiments, the photovoltaic device may further include one or more layers disposed on the transparent layer, such as, for example, a protective layer (not shown). In such instances, the solar radiation may be incident on the protective layer and not on the transparent layer 130 directly.

The rapid thermal annealing method of the present invention may advantageously allow for fabrication of a photovoltaic device using CTO layer in “substrate” configuration. Without being bound by any particular theory, it is believed that the rapid thermal annealing step may heat the amorphous CTO layer much faster than the semiconducting layers (such as CdS, CdTe) due to the greater absorption of the amorphous CTO layer. Accordingly, in some embodiments, the rapid thermal annealing step may allow the amorphous CTO layer to be heated to a temperature greater than the semiconducting layers, thus annealing the CTO layer without altering the properties of the semiconducting layers.

In some embodiments, the first semiconductor layer 140 and the second semiconductor layer 150 may be doped with a p-type dopant or n-type dopant to form a heterojunction. As used in this context, a heterojunction is a semiconductor junction, that is composed of layers of dissimilar semiconductor material. These materials usually have non-equal band gaps. As an example, a heterojunction can be formed by contact between a layer or region of one conductivity type with a layer or region of opposite conductivity, e.g., a “p-n” junction.

In some embodiments, the second semiconductor layer 150 includes an absorber layer. The absorber layer is a part of a photovoltaic device where the conversion of electromagnetic energy of incident light (for instance, sunlight) to electron-hole pairs (that is, to electrical current) occurs. A photo-active material is typically used for forming the absorber layer. Suitable photo-active materials include cadmium telluride (CdTe), cadmium zinc telluride (CdZnTe), cadmium magnesium telluride (CdMgTe), cadmium manganese telluride (CdMnTe), cadmium sulfur telluride (CdSTe), zinc telluride (ZnTe), CuInS2 (copper, indium, sulfur), CIS (copper, indium, selenium), CIGS (copper, indium, gallium, selenium), CIGSS (copper, indium, gallium, selenium, sulfur), iron sulfide (FeS₂), and combinations thereof. The above-mentioned photo-active semiconductor materials may be used alone or in combination. Further, these materials may be present in more than one layer, each layer having different type of photo-active material or having combinations of the materials in separate layers. In one particular embodiment, the second semiconductor layer 150 includes cadmium telluride (CdTe) as the absorber material. CdTe is an efficient photo-active material that is used in thin-film photovoltaic devices. CdTe is relatively easy to deposit and therefore is considered suitable for large-scale production. In one embodiment, the second semiconductor layer 150 has a thickness in a range from about 1500 nm to about 4000 nm.

The first semiconductor layer 140 is disposed adjacent to the transparent layer 130. In a particular embodiment, the first semiconductor layer 140 includes cadmium sulfide (CdS) and may be referred to as the “window layer”. In one embodiment, the first semiconductor layer 140 has a thickness in a range from about 30 nm to about 150 nm. A back contact layer 160 is further disposed adjacent to the second semiconductor layer 150 and is in ohmic contact therewith. Back contact layer 160 may include a metal, semiconductor, or combination thereof. In some embodiments, a back contact layer 160 may include gold, platinum, molybdenum, or nickel, or zinc telluride. In some embodiments, one or more additional layers may be interposed between the second semiconductor layer 150 and the back contact layer 160, such as, for example, a p+-type semiconductor layer. In some embodiments, the second semiconductor layer 150 may include p-type cadmium telluride (CdTe) that may be further treated or doped to reduce the back contact resistance, such as for example, by cadmium chloride treatment or by forming a zinc telluride or copper telluride layer on the backside. In one embodiment, the back contact resistance may be improved by increasing the p type carriers in the CdTe material to form a p+ type layer on the backside of the CdTe material that is in contact with the back contact layer.

In some embodiments, the method further includes disposing a buffer layer 170 between the transparent layer and the first semiconductor layer 140, as indicated, for example in FIG. 6. In one embodiment, the buffer layer 170 includes an oxide selected from the group consisting of tin oxide, indium oxide, zinc oxide, zinc stannate, and combinations thereof. In a particular embodiment, the buffer layer 170 includes tin oxide or ternary mixed oxide thereof.

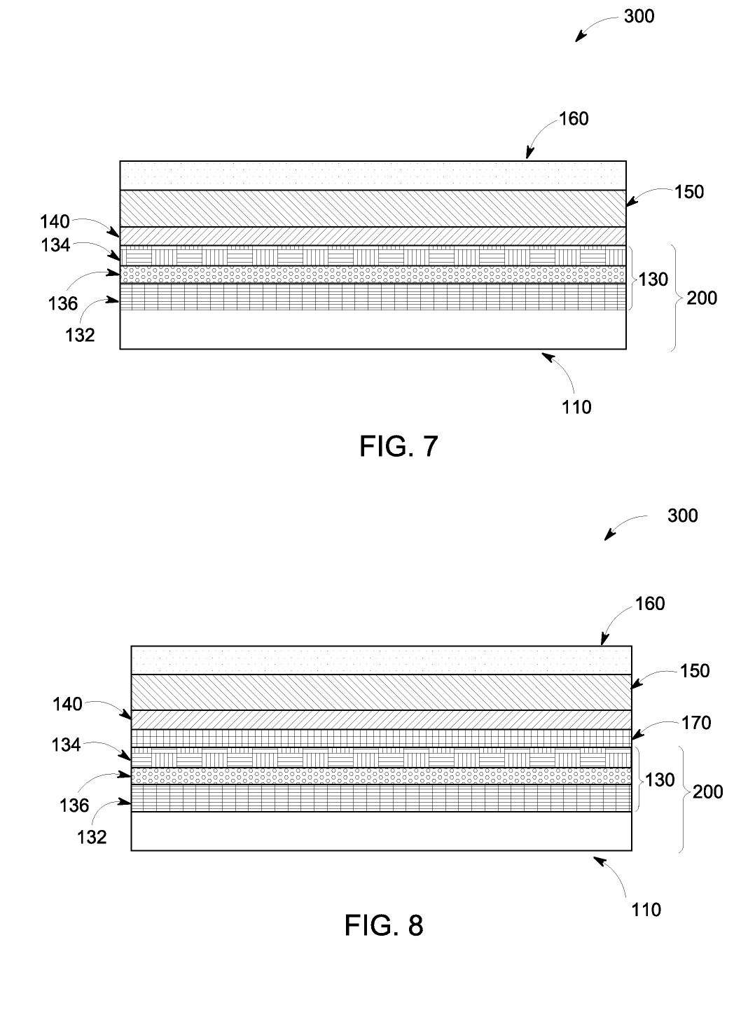

As described above, in some embodiments, the rapid thermal annealing step results in formation of a first region 132, a second region 134, and a transition region 136 in the transparent layer 130. In such instances, as indicated, for example in FIG. 7, the first semiconductor layer or window layer 140 is disposed directly on the transparent layer 130 adjacent to the second region 134 and an intermediate step of depositing an additional buffer layer is not required. In such embodiments, the second region 134 may function as a buffer layer or insulating layer between the second semiconductor layer 150 (for example, CdTe) and the first region 132 (functioning as TCO). Further, the second region 134 may also relieve stress at the interface between the first region 132 (functioning as TCO) and the first semiconductor layer 140 (for example, CdS) and thus create a lower stress level at the CdS/CdTe interface, where defects contribute to lowering the V_{OC} of these devices. Accordingly, the second region 134 within the transparent layer 130 may obviate the need to dispose an additional buffer layer between the CTO layer and the first semiconductor layer 140 (for example, CdS) in certain embodiments.

In some other embodiments, an additional buffer layer 170 is disposed on the transparent layer 130 adjacent to the second region 134 after the rapid thermal annealing step, as indicated, for example in FIG. 8. In such embodiments, the first semiconductor layer 140 is disposed on the buffer layer 170 and the buffer layer 170 is disposed adjacent to the second region 134 such that the second region 134 facilitates disposing of higher quality buffer layer 170 on the cadmium tin oxide (CTO) layer and further reduces the effect of discontinuous interface between the cadmium tin oxide (CTO) layer 132 and the buffer layer 170.

One or more of the first semiconductor layer 140, second semiconductor layer 150, back contact layer 160, or the buffer layer 170 (optional) may be deposited by one or more of the following techniques: sputtering, electrodepositing, screen printing, spraying, physical vapor depositing, or closed space sublimation. One or more of these layers may be further heated or subsequently treated to manufacture the photovoltaic device 300.

### EXAMPLES

The following examples are presented to further illustrate certain embodiments of the present invention. These examples should not be read to limit the invention in any way.

### Example 1

### Rapid Thermal Annealing of CTO Layer Disposed on Borosilicate Glass

Thin films of cadmium tin oxide (CTO) were prepared on borosilicate glass support by DC sputtering at room temperature, using a ceramic target and a sputtering pressure of 16.5 milli Torr. The borosilicate glass support had a thickness of about 1.3 mm Rapid thermal annealing (RTA) process was conducted in an argon atmosphere (˜700 Torr) and used no additional sources of cadmium (to compensate for Cd losses from the film during thermal annealing). Several 0.5 inch×1 inch samples were diced from a 6 inch×6 inch plate resulting in a ˜216 nm thick amorphous CTO film on borosilicate glass. These samples were placed in a sealed quartz tube filled with argon and introduced into a custom designed rapid thermal annealing system, based on a single 2 kilowatts halogen lamp. The halogen lamp was pulsed and a fixed pulse width of 30 seconds was used. The lamp power was varied to explore regions where the required transformation would occur. Depending on the system setting, in some instances the estimated peak temperature of the samples was around ˜900° C., with approximately 30 W/cm² from the incident radiation being absorbed by the sample.

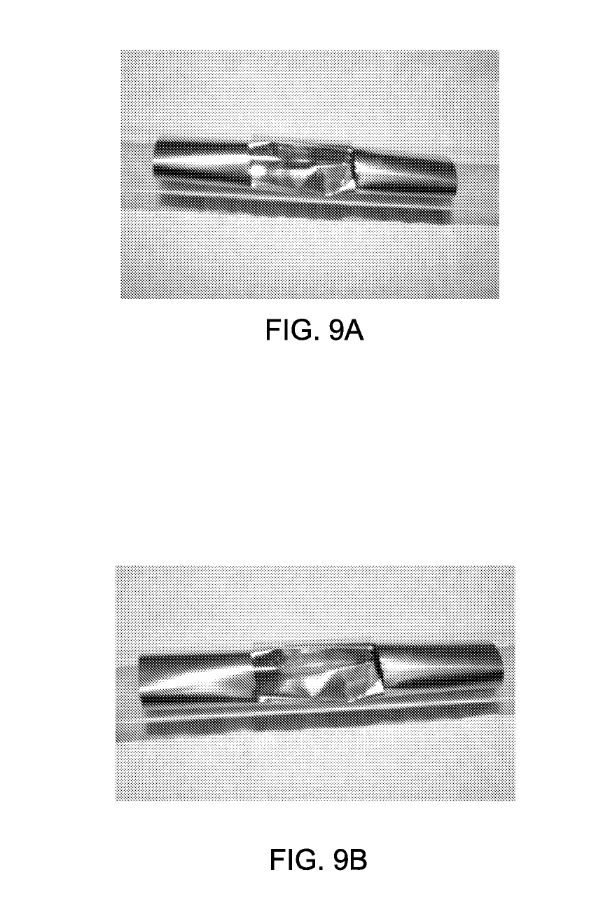

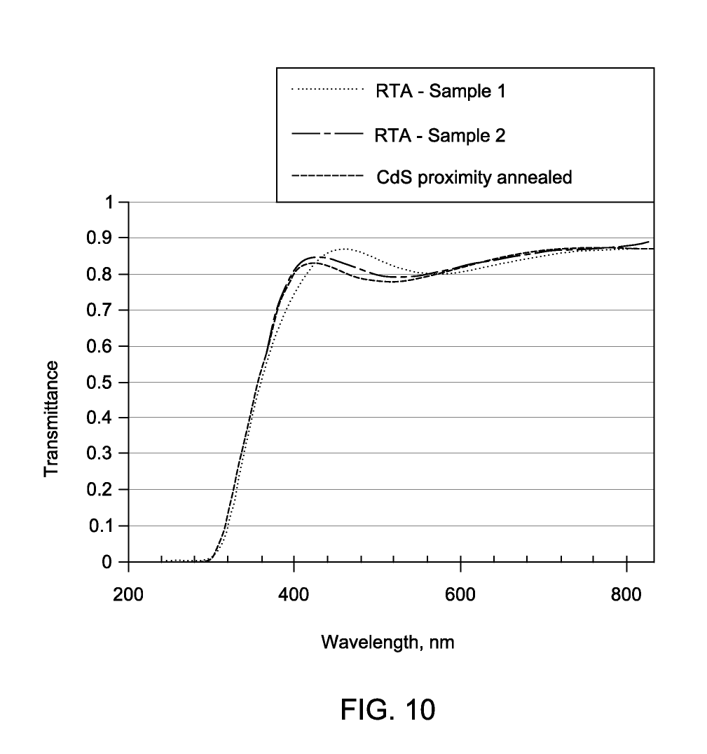

FIGS. 9a and 9b visually capture the effect of rapid thermal annealing (RTA) on a CTO layer disposed on a borosilicate glass support. FIG. 9a shows the digital image of a CTO film before annealing and FIG. 9b shows the digital image of a CTO film after annealing. An improvement in transparency as a result of a single RTA cycle was clearly visible to the naked eye. FIG. 10 shows the optical transmittance of two samples (samples 1 and 2) annealed using RTA compared to the transmittance curve obtained for a CTO film deposited under similar conditions and annealed at ˜630° C. using the CdS-proximity annealing process. Qualitatively, the transmittance curve obtained with RTA is very similar to that obtained after the proximity annealing process.

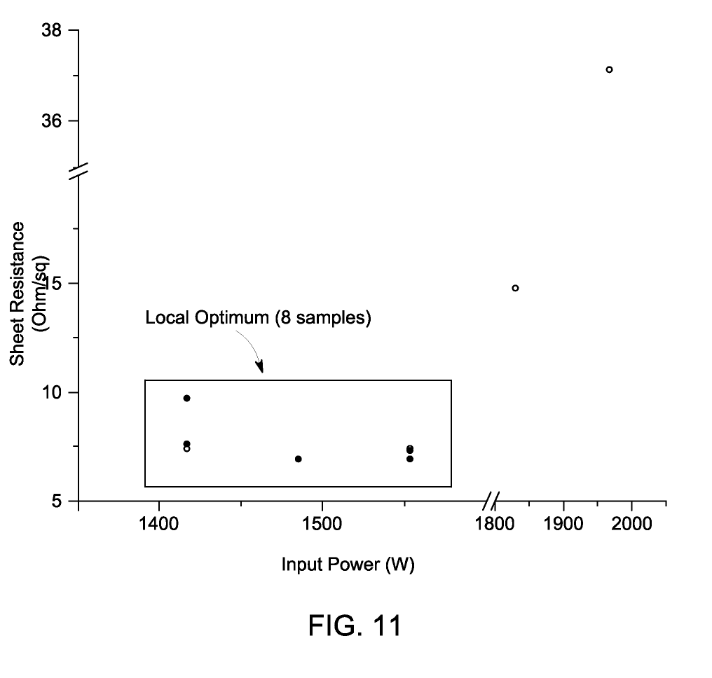

The sheet resistance of the CTO films was measured before and after RTA using a 4-point probe. Before RTA the sheet resistance of the films was too high to be measured. FIG. 11 show the sheet resistance measured for CTO films after RTA as a function of input power to the halogen lamp. The results of the RTA experiments showed that a minimum sheet resistance of ˜7 ohms/square was obtained at a power ˜1.5 kilowatts and there was a relatively wide range of power (1.42-1.55 kilowatts) for which the sheet resistance remained very close to the minimum value (˜7 ohms/square). With increasing power the sheet resistance continued to rise beyond the minimum point.

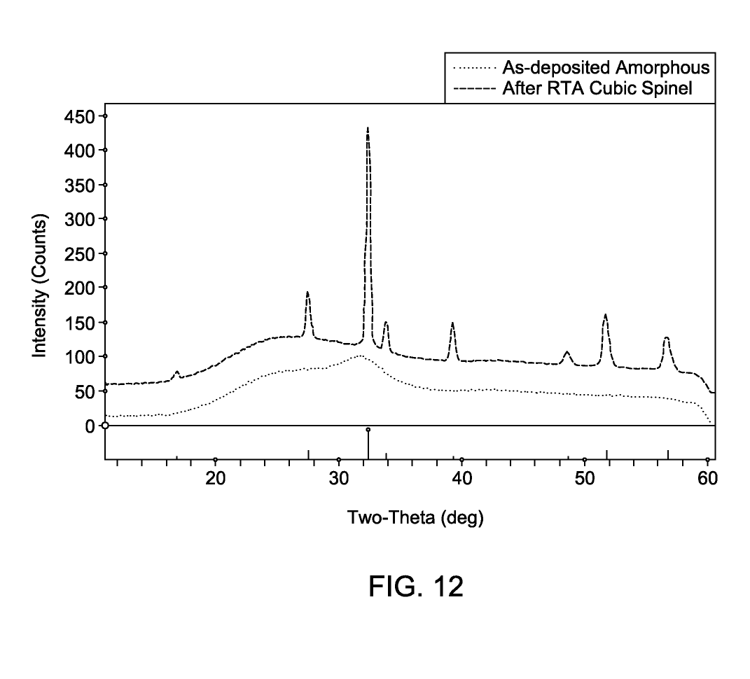

FIG. 12 shows the x-ray diffraction (XRD) pattern for the unannealed and RTA annealed samples. As seen in FIG. 12, no XRD pattern is observed for the as-deposited amorphous CTO films. In contrast, distinct peaks corresponding to crystalline cubic spinel phase of cadmium tin oxide were observed for CTO films after the RTA step. In some samples, a small peak at two-theta ˜30 degrees was also detected, suggesting the presence of tin oxide.

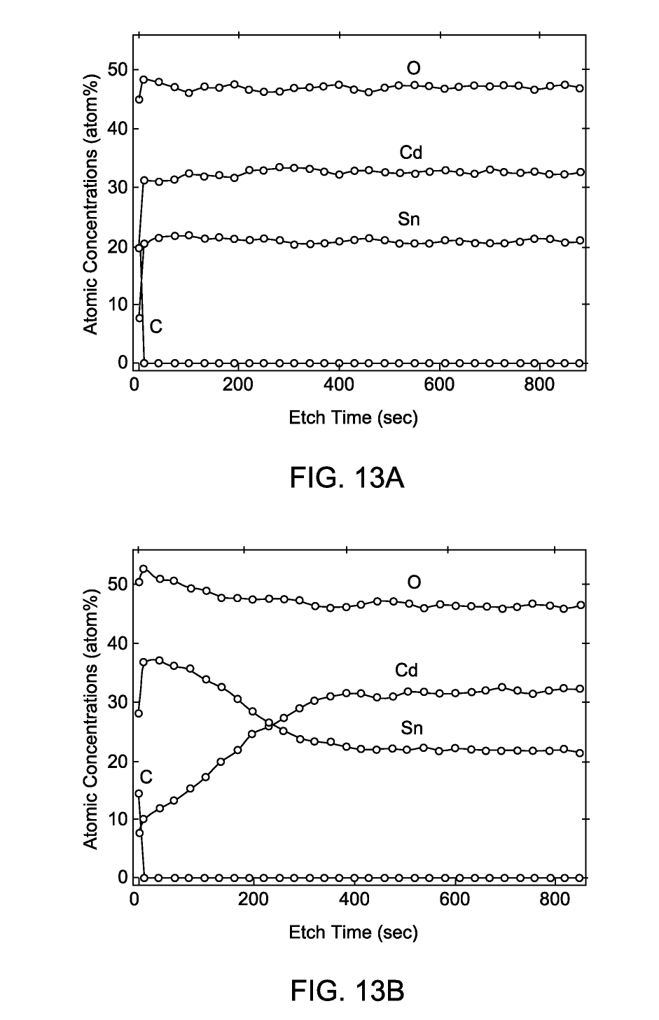

FIG. 13a shows the x-ray photoelectron spectroscopy (XPS) profile of as-deposited substantially amorphous CTO film illustrating that the cadmium to tin atomic ratio is homogeneous across the thickness of the film. FIG. 13b shows the XPS profile of CTO film after being subjected to RTA. FIG. 13b illustrates that after annealing, the CTO film shows at least two different concentration profiles: (a) a first region showing a substantially constant atomic ratio of cadmium to tin for etch times in the range greater than about 400 seconds and (b) a cadmium-depleted region for etch times in the range of 0 second to about 400 seconds. As illustrated in FIG. 13b, the first region has substantially the same atomic ratio of cadmium to tin as observed for the as-deposited amorphous cadmium tin oxide film (FIG. 13a). Further, the XPS profile in FIG. 13b confirms the presence of a cadmium-depleted region having a thickness of about 50 nm after the annealing step.

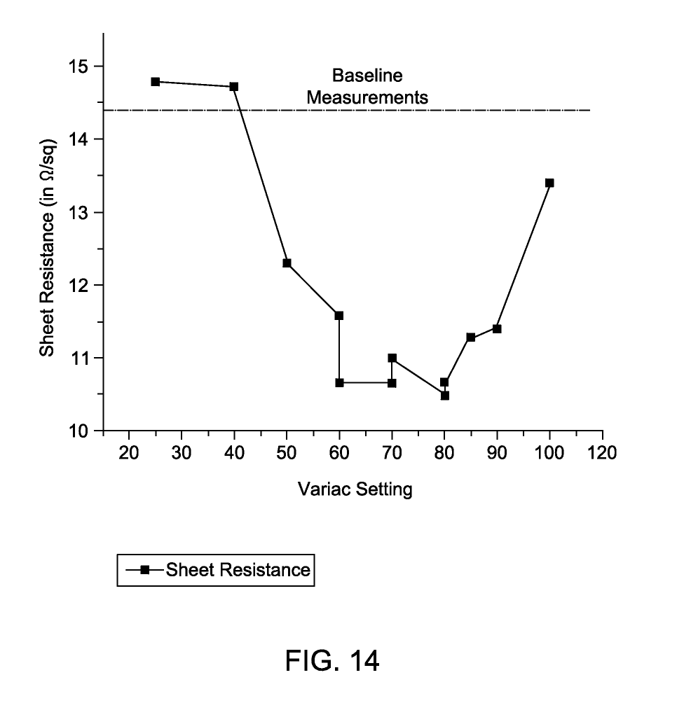

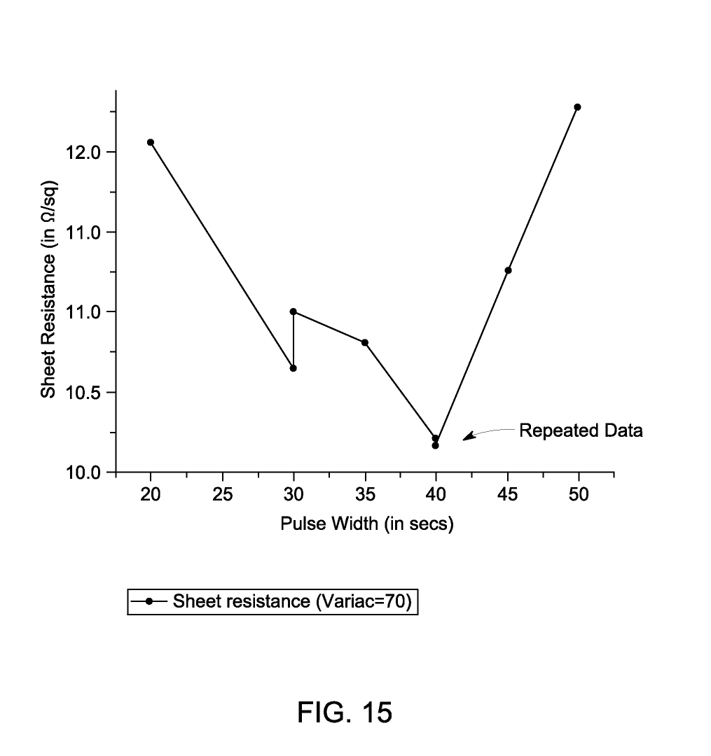

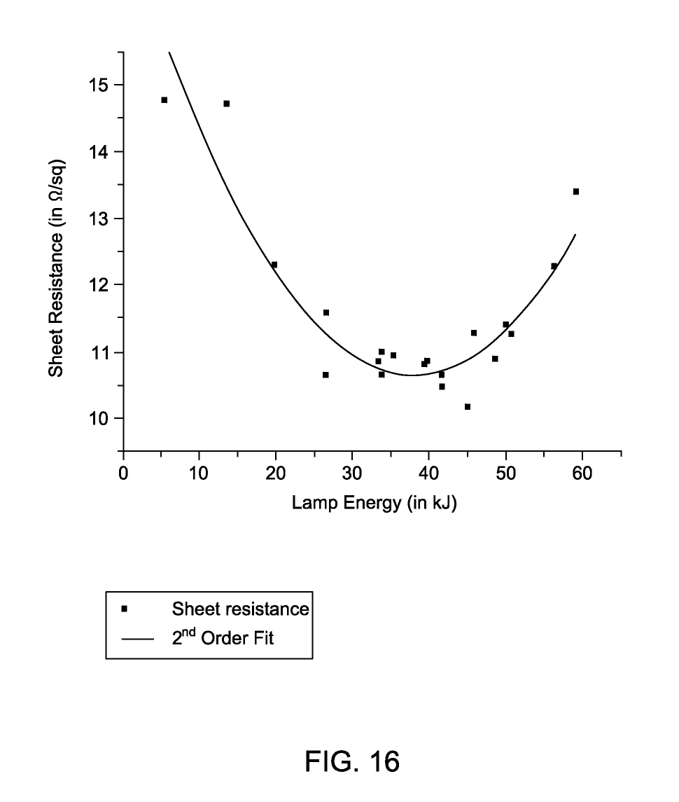

FIGS. 14-16 show the sheet resistance values of RTA-annealed CTO films as a function of variac setting (in units of percentage of maximum voltage), pulse width, and lamp power, respectively. FIGS. 14-16 illustrate that the electrical properties of the RTA-annealed CTO films may be controlled by varying the processing parameters used for RTA.

### Example 2

### Rapid Thermal Annealing of CTO Layer Disposed on Soda-Lime Glass

Three films of CTO were prepared on soda-lime glass supports by DC sputtering at room temperature, using a ceramic target and a sputtering pressure of 16 milli Torr. The soda-lime glass support had a thickness of about 3.2 mm CTO films on soda-lime glass support were subjected to RTA using the method as described above in Example 1. However, for CTO films disposed on soda-lime glass support, the rapid thermal annealing treatment was repeated 3 to 4 times using a pulse width of 30 seconds for each cycle. The total time duration for the annealing step was about 2 minutes.

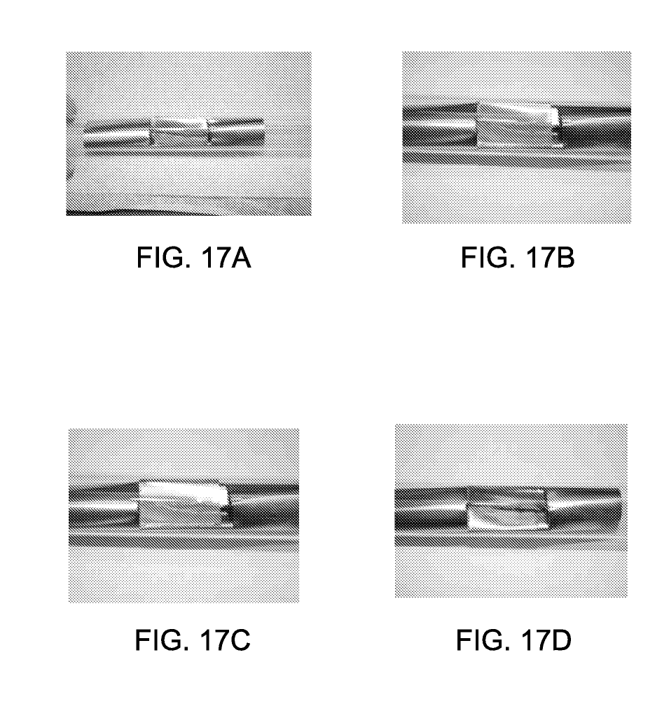

FIG. 17 shows the progression towards improved optical transparency with each successive annealing cycle. The slower annealing rate of CTO films on soda-lime glass may be due to the thicker soda-lime glass support (3.2 mm) causing a different thermal profile to occur when compared with the thinner (1.3 mm) borosilicate glass support.

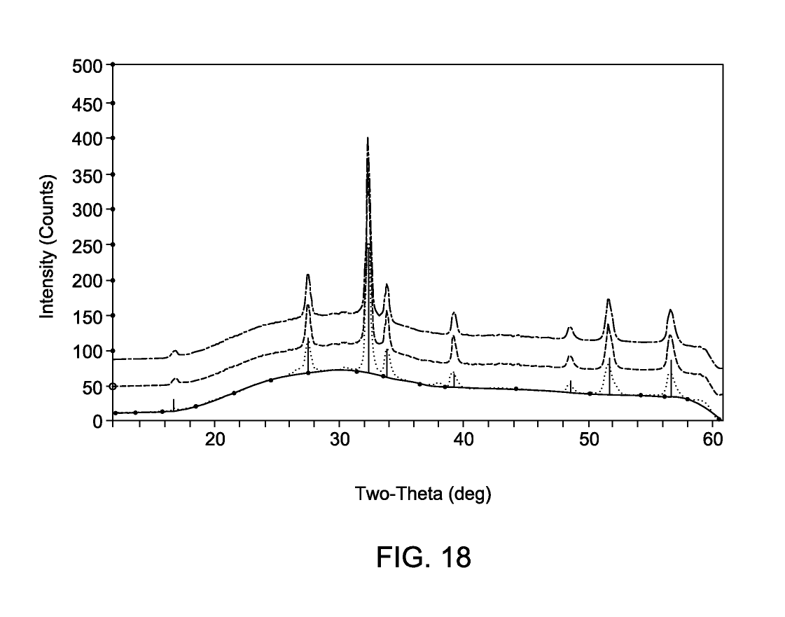

FIG. 18 shows the XRD patterns for the three samples annealed via RTA, illustrating the conversion of amorphous CTO to crystalline, cubic spinel phase. The demonstration of crystalline CTO formation on soda-lime glass using RTA indicates that even though the temperatures achieved during the RTA step range between 800-900° C., a crystalline CTO film can be obtained without apparent damage to the soda-lime glass support. As noted earlier, soda-lime glass is a more economical support choice, but because of its softening temperature being greater than 550° C., it's use as a support is precluded in the CdS-proximity annealing process (˜630° C.).

The averaged sheet resistance of the RTA-annealed CTO films disposed on soda-lime glass support was 7.6±0.9 ohms/square, which was only slightly higher than the average sheet resistance of CTO films disposed on borosilicate glass (7.1±0.2 ohms/square)

The foregoing examples are merely illustrative, serving to exemplify only some of the features of the invention. The appended claims are intended to claim the invention as broadly as it has been conceived and the examples herein presented are illustrative of selected embodiments from a manifold of all possible embodiments. Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of:” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

1. A method, comprising:
disposing a substantially amorphous, electrically resistive cadmium tin oxide layer on a support; and
rapidly thermally annealing the substantially amorphous cadmium tin oxide layer by exposing a first surface of the substantially amorphous cadmium tin oxide layer to an electromagnetic radiation emitted from an incoherent light source to form a transparent layer.

2. The method of claim 1, wherein rapid thermal annealing comprises irradiating the first surface of the substantially amorphous CTO layer at an incident power density in a range greater than about 200 Watts/cm².

3. The method of claim 1, wherein the electromagnetic radiation comprises infra-red radiation, ultra-violet radiation, or combinations thereof.

4. The method of claim 1, wherein the electromagnetic radiation has a wavelength in a range less than about 600 nm.

5. The method of claim 1, wherein the electromagnetic radiation has a wavelength in a range from about 450 nm to about 600 nm.

6. The method of claim 1, wherein the electromagnetic radiation has a wavelength in a range less than about 300 nm.

7. The method of claim 1, wherein the incoherent light source is selected from a group consisting of a halogen lamp, an ultra-violet lamp, a high intensity discharge lamp, and combinations thereof.

8. The method of claim 1, wherein rapid thermal annealing comprises heating the substantially amorphous cadmium tin oxide layer at a treatment temperature in a range from about 700° C. to about 1000° C.

9. The method of claim 1, wherein rapid thermal annealing comprises exposing the substantially amorphous cadmium tin oxide layer to the electromagnetic radiation for a time duration in a range from about 10 seconds to about 40 seconds.

10. The method of claim 1, wherein rapid thermal annealing comprises heating the substantially amorphous cadmium tin oxide layer at a heating rate greater than about 20° C./s.

11. The method of claim 1, wherein rapid thermal annealing comprises exposing the first surface of the substantially amorphous cadmium tin oxide layer to the electromagnetic radiation in an atmosphere comprising oxygen, argon, nitrogen, hydrogen, helium, or combinations thereof.

12. (canceled)

13. The method of claim 1, wherein the support has a softening temperature in a range less than about 600° C.

14. The method of claim 1, wherein the support comprises borosilicate glass or soda-lime glass.

15. The method of claim 1, wherein the transparent layer comprises cadmium tin oxide having a substantially single-phase spinel crystal structure.

16. The method of claim 1, wherein the transparent layer comprises:
(a) a first region comprising cadmium tin oxide; and
(b) a second region comprising tin and oxygen, wherein an atomic concentration of cadmium in the second region is less than an atomic concentration of cadmium in the first region.

17. The method of claim 16, wherein the atomic concentration of cadmium in the second region is less than about 20%.

18. The method of claim 16, wherein the second region is substantially free of cadmium.

19. The method of claim 16, wherein the second region has an electrical resistivity greater than an electrical resistivity of the first region.

20. The method of claim 16, further comprising a transition region interposed between the first region and the second region, wherein the transition region comprises cadmium, tin, and oxygen, and an atomic ratio of cadmium to tin in the transition region varies across a thickness of the transition region.

21. The method of claim 1, wherein the transparent layer has a thickness in a range from about 100 nm to about 600 nm.

22. The method of claim 1, wherein the transparent layer has an electrical resistivity less than about 2×10⁻⁴ Ohms-cm.

23. The method claim 1, wherein the transparent layer has an average optical transmission greater than about 80%.

24. A method, comprising:
disposing a substantially amorphous, electrically resistive cadmium tin oxide layer on a support; and rapidly thermally annealing the substantially amorphous cadmium tin oxide layer by exposing a first surface of the substantially amorphous cadmium tin oxide layer to an electromagnetic radiation emitted from an incoherent light source to form a transparent layer;
disposing a first semiconductor layer on the transparent layer;
disposing a second semiconductor layer on the first semiconductor layer; and
disposing a back contact layer on the second semiconductor layer to form a photovoltaic device.

25. The method of claim 24, wherein the first semiconductor layer comprises cadmium sulfide.

26. The method of claim 24, wherein the second semiconductor layer comprises cadmium telluride.

27. The method of claim 24, further comprising disposing a buffer layer between the transparent layer and the first semiconductor layer.

28. The method of claim 24, wherein the buffer layer comprises an oxide selected from a group consisting of tin oxide, indium oxide, zinc oxide, and combinations thereof.

29. A method, comprising:
disposing a substantially amorphous, electrically resistive cadmium tin oxide layer on a support; and
rapidly thermally annealing the substantially amorphous cadmium tin oxide layer by exposing a first surface of the substantially amorphous cadmium tin oxide layer to an electromagnetic radiation emitted from an incoherent light source to form a transparent layer; and
wherein the transparent layer comprises cadmium tin oxide having a substantially single-phase spinel crystal structure, and the transparent layer has an electrical resistivity less than about 2×10⁻⁴ Ohm-cm.

30. The method of claim 1, wherein rapid thermal annealing comprises heating the substantially amorphous cadmium tin oxide layer at a treatment temperature in a range from about 800° C. to about 1000° C.
